(19) United States
(12) Patent Application Publication
(10) Pub. No.: US 2026/0227688 A1
(43) Pub. Date: Aug. 6, 2026

(54) PELLICLE AND PHOTOMASK ASSEMBLY

(71) Applicant: Samsung Electronics Co., Ltd., Suwon-si (KR)

(72) Inventors: Mun Ja Kim, Suwon-si (KR); Ouiserg Kim, Suwon-si (KR); Junhyung Kim, Suwon-si (KR); Changhwan Kim, Suwon-si (KR); Young Duk Suh, Suwon-si (KR); Seongju Wi, Suwon-si (KR)

(73) Assignee: Samsung Electronics Co., Ltd., Suwon-si (KR)

(21) Appl. No.: 19/237,829

(22) Filed: Jun. 13, 2025

(30) Foreign Application Priority Data
Feb. 5, 2025 (KR) 10-2025-0014406

(51) Int. Cl. G03F 1/64

(52) U.S. Cl. CPC G03F 1/64

(57) ABSTRACT

A pellicle includes a pellicle membrane formed of carbon nanotubes; and a frame directly contacting and connected to a peripheral edge of one side of the pellicle membrane.

### CROSS-REFERENCE TO RELATED APPLICATIONS

This present application claims priority to and the benefit under 35 USC § 119(a)-(d) of Korean Patent Application No. 10-2025-0014406, filed on Feb. 5, 2025, in the Korean Intellectual Property Office, the entire disclosure of which is incorporated herein by reference.

### BACKGROUND

The present inventive concept relates to a pellicle and a photomask assembly.

In the wafer manufacturing process, a lithography process may be used to form a circuit pattern on a wafer. In the lithography process, a photomask is used to transfer a desired pattern onto a substrate. If the photomask is contaminated by foreign substances such as particles from the surrounding environment or deformed by the surrounding environment, a defect may occur on the wafer to which the pattern of the photomask is transferred. Therefore, a pellicle is provided that is combined with the photomask to protect the photomask from being contaminated or deformed by foreign substances or the surrounding environment.

### SUMMARY

Example embodiments provide a pellicle and photomask assembly capable of minimizing deformation of the pellicle.

Example embodiments provide a pellicle and photomask assembly capable of minimizing deformation and stress of the pellicle by arranging the pellicle membrane in a free-standing structure on a frame.

According to example embodiments, a pellicle includes a pellicle membrane formed of carbon nanotubes; and a frame directly contacting and connected to a peripheral edge of one side of the pellicle membrane.

According to example embodiments, a pellicle includes a pellicle membrane formed of carbon nanotubes; and a frame including a first surface directly contacting and connected to a peripheral edge of one side of the pellicle membrane and a second surface, facing the first surface. The frame may include a plurality of grooves in the form of slits that are respectively arranged on an inner peripheral wall surface and an outer peripheral wall surface of the frame and intersect one another along a peripheral direction of the frame and penetrate the first surface of the frame and the second surface of the frame.

According to example embodiments, a photomask assembly includes a photomask having a coupling surface; and a pellicle including a pellicle membrane formed of carbon nanotubes and a frame having a first surface directly contacting and connected to a peripheral edge of one side of the pellicle membrane and a second surface coupled to the coupling surface.

### BRIEF DESCRIPTION OF THE DRAWINGS

The above and other aspects, features, and advantages of the present inventive concept will be more clearly understood from the following detailed description, taken in conjunction with the accompanying drawings, in which:

FIG. 1 is an exemplary diagram illustrating a photomask assembly according to embodiments.

FIG. 2 is an exemplary diagram illustrating a pellicle according to embodiments.

FIG. 3 is an exemplary diagram illustrating a pellicle according to embodiments.

FIG. 4 is an exemplary diagram illustrating a pellicle according to embodiments.

FIG. 5 is an exemplary diagram illustrating a frame of a pellicle according to embodiments.

FIG. 6 is an exemplary diagram illustrating a part of a side wall of the frame in FIG. 5.

FIG. 7 is an exemplary diagram illustrating a frame of a pellicle according to embodiments.

FIG. 8 is an exemplary diagram illustrating a part of a side wall of the frame in FIG. 7.

FIG. 9 is an exemplary diagram illustrating a frame of a pellicle according to embodiments.

FIG. 10 is an exemplary diagram illustrating a part of a side wall of the frame in FIG. 9. FIG. 11 is an exemplary diagram illustrating a photomask assembly according to embodiments.

### DETAILED DESCRIPTION

Hereinafter, example embodiments will be described with reference to the accompanying drawings.

In the circumstance of a pellicle provided with a photomask, a membrane having a thin thickness and high transmittance is being developed considering the economic feasibility of the lithography process. The pellicle including the above membrane may be deformed when various processes such as the mounting process with the photomask or the lithography process are performed, which may cause defects on the wafer and lower the quality of the wafer.

### Embodiment 1

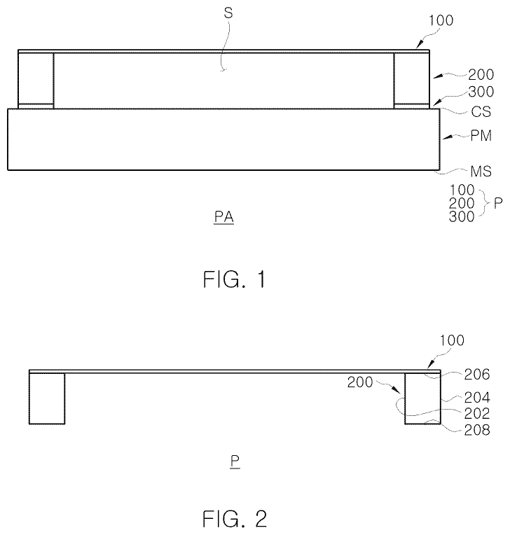

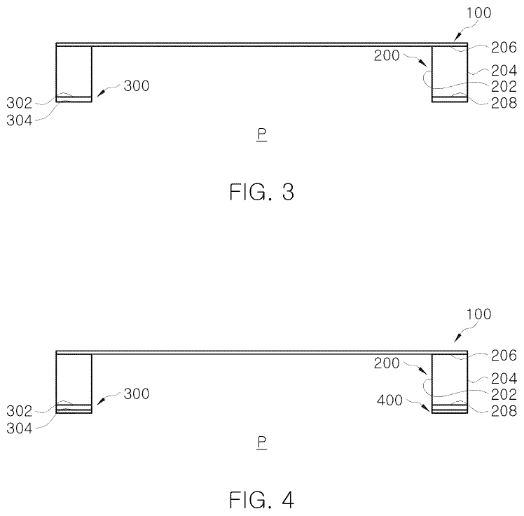

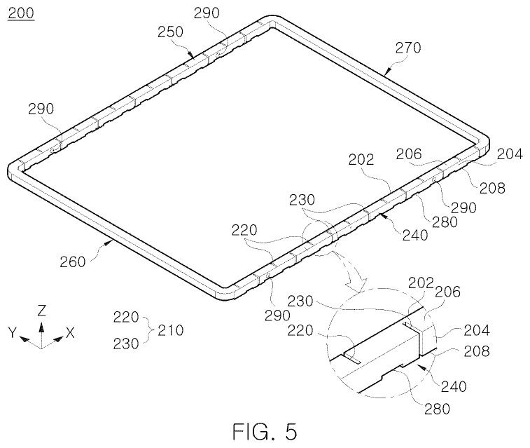

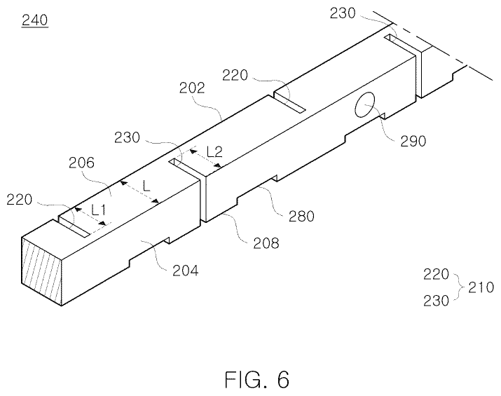

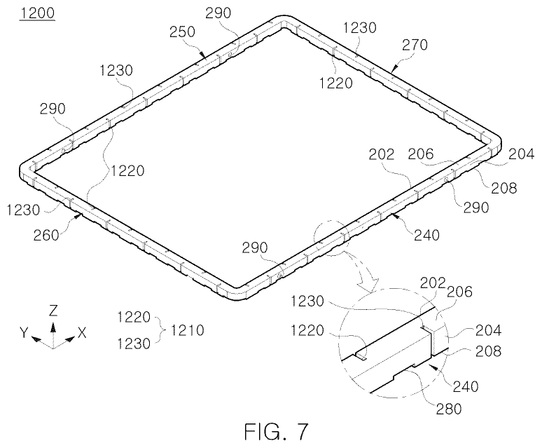

FIG. 1 is an exemplary drawing illustrating a photomask assembly according to embodiments, FIGS. 2 to 4 are exemplary drawings illustrating a pellicle according to embodiments, FIG. 6 is an exemplary drawing illustrating a part of a side wall of a frame in FIG. 5, and FIG. 7 is an exemplary drawing illustrating a frame of a pellicle according to embodiments.

Referring to FIG. 1, a photomask assembly (PA) according to Embodiment 1 of the present inventive concept may include a photomask (PM) and a pellicle (P) protecting the photomask (PM) from the outside.

The photomask (PM) may be applied as a photomask used in an extreme ultraviolet (EUV) photolithography process. The above photomask (PM) may include a coupling surface (CS) to which a pellicle (P) is coupled, and a mounting surface (MS) that faces the coupling surface (CS) and is mounted on a photomask stage (not illustrated) of an exposure device that holds the photomask (PM) during a photolithography process.

The pellicle (P) may protect the photomask from external defects during an EUV lithography process, thereby preventing damage such as contamination by foreign substances such as particles or deformation due to the surrounding environment, and may minimize deformation and stress of the pellicle (P).

Referring to FIGS. 1 to 4, the pellicle (P) according to embodiments may include a pellicle membrane (100) and a frame (200) that supports the pellicle membrane (100).

The pellicle membrane (100) may be formed of carbon nanotubes. The above pellicle membrane (100) may have a thickness sufficiently thin to allow EUV light or electron beams to transmit therethrough. The pellicle membrane (100) may have a transmittance of 90% or more. In embodiments, the pellicle membrane (100) may have a transmittance of 95% or more. However, in the present embodiment, the pellicle membrane (100) is not limited to the above transmittance range and may be appropriately changed according to various lithography process conditions. The pellicle membrane (100) may be composed of a carbon nanotube layer having a thickness of several nm to several tens nm to secure a transmittance above a certain standard. In embodiments, the pellicle membrane (100) may be a carbon nanotube layer having a thickness of less than or equal to 20 nm, but is not limited thereto. In embodiments, the pellicle membrane (100) may have a very thin thickness of about 5 nm to 20 nm. Since the above pellicle membrane (100) may be safely supported on the frame (200) by being able to stand freely over a large area due to its own structure, the pellicle membrane (100) may not include a support layer or a reinforcing layer that serves as a separate support layer.

The frame (200) may be connected to the peripheral edge of one side of the pellicle membrane (100). The frame (200) may be placed between the pellicle membrane (100) and the photomask (PM) when combined with the photomask (PM). The frame (200) may be configured in various shapes, and in embodiments, the frame (200) may be configured in various shapes such as a quadrangular shape or a circular shape formed in a closed shape. In embodiments, as illustrated in FIG. 5, the frame (200) may be configured in a quadrangular shape. The frame (200) may include an inner peripheral wall surface (202), an outer peripheral wall surface (204), and a first surface (206) and a second surface (208) that connect both ends of the inner peripheral wall surface (202) and the outer peripheral wall surface (204) and face one another. The first surface (206) of the frame (200) may be a surface connected to a peripheral edge of one side of the pellicle membrane (100). The second surface (208) of the frame (200) may be a surface connected to a photomask (PM) and may be coupled to a coupling surface (CS) of the photomask (PM). When coupled, the pellicle (P) and the photomask (PM) may form a closed space (S) therein. The inner peripheral wall surface (202) of the frame (200) may refer to a side wall surface forming the closed space (S), and the outer peripheral wall surface (204) of the frame (200) may refer to a side wall surface that is opposite to the inner peripheral wall surface (202) and faces the outside of the frame (200). The first surface (206) of the frame (200) may be connected by directly contacting the peripheral edge of one side of the pellicle membrane (100). In embodiments, the first surface (206) of the frame (200) may be connected by directly contacting the peripheral edge of one side of the pellicle membrane (100) without the intervention of a separate connecting means such as an adhesive layer, by utilizing the van der Waals force between the one side of the pellicle membrane (100) and the first surface (206) of the frame (200). Accordingly, it is possible to reduce the process and the resulting risks and time required by arranging a separate adhesive layer or other connecting means, and to easily implement mass production of pellicles (P).

The frame (200) may be composed of various materials. In embodiments, the frame (200) may be composed of a metal material or a polymer material having excellent heat resistance. In embodiments, the frame (200) may include at least one of aluminum, zinc, magnesium, stainless steel, molybdenum, zirconium, tungsten, carbon, diamond-like carbon (DLC), and silicon. However, the material of the frame (200) in the present inventive concept is not limited to the materials described above, and may be comprised of various materials.

The second surface (208) of the frame (200) may be coupled to the coupling surface (CS) of the photomask (PM) by an adhesive means. In embodiments, as illustrated in FIG. 4, the pellicle (P) may further include an adhesive layer (300) adhering the frame (200) and the photomask (PM). The adhesive layer (300) may be disposed on the second surface (208) of the frame (200) and adhered to the coupling surface (CS) of the photomask (PM). The adhesive layer (300) may include a frame adhesive surface (302) disposed on the second surface (208) of the frame (200) and a photomask adhesive surface (304) adhered to the coupling surface (CS) of the photomask (PM). The frame adhesive surface (302) of the adhesive layer (300) may be one surface of the adhesive layer (300) facing the second surface (208) of the frame (200), and the photomask adhesive surface (304) of the adhesive layer (300) may be the other surface of the adhesive layer (300) facing the second surface (208) of the frame (200) and the frame adhesive surface (302) of the adhesive layer (300). Accordingly, the frame (200) and the photomask (PM) may be bonded by the adhesive layer (300). The adhesive layer (300) may be formed on the second surface (208) of the frame (200) in advance before bonding the pellicle (P) to the photomask (PM), or may be formed by a mounting process of bonding the pellicle (P) to the photomask (PM). For example, during a mounting process for bonding a pellicle (P) to a photomask (PM), an adhesive may be applied to the coupling surface (CS) of the photomask (PM) and then the pellicle (P) may be bonded to the photomask (PM) to form an adhesive layer (300) between the pellicle (P) and the photomask (PM). The adhesive layer (300) may be composed of various materials. The adhesive layer (300) may include a viscoelastic adhesive having excellent heat resistance. In embodiments, the adhesive layer (300) may include a hot melt adhesive. The adhesive layer (300) may include, for example, a styrene-based hot melt adhesive; however, the adhesive layer (300) in the present inventive concept is not limited thereto, and temperature, chemical, mechanical properties, etc. may be appropriately changed in various ways depending on the specific environment to which the pellicle (P) and the photomask assembly (PA) are applied.

In embodiments, as illustrated in FIG. 5, the photomask assembly (PA) may further include a protective film (400) to protect the adhesive layer (300) of the pellicle (P) before the pellicle (P) is bonded to the photomask (PM). The protective film (400) may be detachably disposed on the photomask adhesive surface (304) of the adhesive layer (300). Accordingly, when a mounting process for bonding the pellicle (P) and the photomask (PM) is performed, the protective film (400) may be removed from the photomask adhesive surface (304) of the adhesive layer (300), and then the pellicle (P) and the photomask (PM) may be bonded and bonded by the adhesive layer (300).

In embodiments, referring to FIGS. 5 and 6, the frame (200) may include a plurality of grooves (210) arranged on the frame (200). The plurality of grooves (210) may be arranged on an inner peripheral wall surface (202) and an outer peripheral wall surface (204) of the frame (200) along a circumferential direction of the frame (200), respectively. In embodiments, the frame (200) may include a plurality of first grooves (220) arranged on the inner peripheral wall surface (202) of the frame (200) and a plurality of second grooves (230) arranged on the outer peripheral wall surface (204) of the frame (200).

A plurality of first grooves (220) may be spaced apart along the circumferential direction of the frame (200) and may be arranged to extend from the inner peripheral wall surface (202) of the frame (200) toward the outer peripheral wall surface (204). The plurality of first grooves (220) may penetrate the first surface (206) and the second surface (208) of the frame (200) and may have a slit shape that extends long from the inner peripheral wall surface (202) of the frame (200) toward the outer peripheral wall surface (204). In embodiments, the plurality of first grooves (220) may have a first extension length (L1) that extends from the inner peripheral wall surface (202) of the frame (200) toward the outer peripheral wall surface (204) of the frame (200) in a direction perpendicular to the inner peripheral wall surface (202). In embodiments, the first extension length (L1) of the plurality of first grooves (220) may be 50% to 90% of the distance (L) between the inner peripheral wall surface (202) and the outer peripheral wall surface (204) of the frame (200). In embodiments, the spacing between the plurality of first grooves (220) may be the same, but is not limited thereto.

A plurality of second grooves (230) may be spaced apart from one another in the circumferential direction of the frame (200) and may extend from the outer peripheral wall surface (204) of the frame (200) toward the inner peripheral wall surface (202). The plurality of second grooves (230) may penetrate the first surface (206) and the second surface (208) of the frame (200) and may have a slit shape extending from the outer peripheral wall surface (204) of the frame (200) toward the inner peripheral wall surface (202). In embodiments, the plurality of second grooves (230) may have a second extension length (L2) extending from the outer peripheral wall surface (204) of the frame (200) toward the inner peripheral wall surface (202) in a direction perpendicular to the outer peripheral wall surface (204). In embodiments, the second extension length (L2) of the plurality of second grooves (230) may be 50% to 90% of the distance (L) between the inner peripheral wall surface (202) and the outer peripheral wall surface (204) of the frame (200). In embodiments, the spacing between the plurality of second grooves (230) may be the same, but is not limited thereto. In addition, in embodiments, the spacing between the plurality of first grooves (230) and the spacing between the plurality of second grooves (230) may be the same, and the spacing between the first grooves (220) and the second grooves (230) adjacent to one another in the circumferential direction of the frame (200) may be spaced apart from one another equally, but is not limited thereto, and may be appropriately arranged as needed.

The plurality of first grooves (220) and the plurality of second grooves (230) may be arranged parallel to one another. In embodiments, the plurality of first grooves (220) and the plurality of second grooves (230) may be arranged to intersect one another along the circumferential direction of the frame (200). The deformation in the thickness direction of the frame (200) may be improved by the structure of the groove (210) including the plurality of first grooves (220) and the plurality of second grooves (230).

The plurality of first grooves (220) and the plurality of second grooves (230) may be arranged on at least a portion of the side walls of the frame (200) that face one another.

In embodiments, when the frame (200) is configured in a quadrangular shape, it may include a first side wall (240) and a second side wall (250) that are opposed to one another, and a third side wall (260) and a fourth side wall (270) that connect both ends of the first side wall (240) and the second side wall (250). The first side wall (240) and the second side wall (250) may be perpendicular to the third side wall (260) and the fourth side wall (270), and the frame (200) may be configured in a rectangular shape. To facilitate explanation in the present inventive concept, the direction in which the first side wall (240) and the second side wall (250) of the frame (200) extend is defined as the first direction (X), the direction in which the third side wall (260) and the fourth side wall (270) of the frame (200) extend is defined as the second direction (Y), and the thickness direction of the frame (200) is defined as the third direction (Z). When the photolithography process is performed while the above pellicle (P) is combined with the photomask (PM), the frame (200) and the photomask (PM) may be reciprocated together along the first direction (X) to perform exposure processing on the substrate.

The plurality of first grooves (220) and the plurality of second grooves (230) may be arranged on the first side wall (240) and the second side wall (250) or on the third side wall (260) and the fourth side wall (270). In embodiments, as illustrated in FIG. 5, the plurality of first grooves (220) and the plurality of second grooves (230) may be arranged on the first side wall (240) and the second side wall (250). Accordingly, the deformation of the frame (200) may be minimized by the structure of the groove (210) including the plurality of first grooves (220) and the plurality of second grooves (230), and in particular, the deformation of the frame (200) in the third direction (Z) may be improved. Furthermore, even if a gap occurs in the first direction (X) of the frame (200) during the process of the frame (200) reciprocating along the first direction (X), the gap may be compensated for by the zigzag arrangement of the plurality of first grooves (220) and the plurality of second grooves (230), so that the deformation of the frame (200) in the first direction (X) may be significantly reduced.

In embodiments, the frame (200) may include a plurality of adhesive grooves (280) arranged on the second surface (208). A plurality of adhesive grooves (280) may be spaced apart from one another in the circumferential direction of the frame (200) on the second surface (208) of the frame (200). Accordingly, a part of the adhesive layer (300) may be accommodated in the adhesive groove (280) to prevent the adhesive material from overflowing. For example, during a mounting process for bonding a pellicle (P) to a photomask (PM), a part of the adhesive may be accommodated in the adhesive groove (280) to form the adhesive layer (300) between the pellicle (P) and the photomask (PM) without the overflow phenomenon. In embodiments, each of the adhesive grooves (280) may be positioned between the first groove (220) and the second groove (230) which are adjacent to one another on the second surface (208) of the frame (200), but is not limited thereto.

In embodiments, a vent hole (290) may be formed in the frame (200) penetrating the inner peripheral wall surface (202) and the outer peripheral wall surface (204) of the frame (200). The vent hole (290) may connect the closed space (S) formed inside when the pellicle (P) and the photomask (PM) are combined with the outside of the photomask assembly (PA). The vent hole (290) may be configured in various shapes, such as a circle. The vent hole (290) may be arranged in various arrangement forms in the frame (200). In embodiments, when the frame (200) is configured in a quadrangular shape, at least one vent hole (290) may be formed in one or more side walls of the four side walls (the first side wall (240), the second side wall (250), the third side wall (260), and the fourth side wall (270)) of the frame (200). Accordingly, it is possible to prevent excessive pressure from being applied to the frame (200) through the vent hole (290) and to maintain the pressure of the closed space (S) and the outside of the photomask assembly (PA) to be the same, thereby effectively preventing deformation of the pellicle membrane (100) due to a pressure difference between the closed space (S) and the outside of the photomask assembly (PA).

In the above, the first groove (220) and the second groove (230) are described as being arranged on the first side wall (240) and the second side wall (250) of the frame (200), but this is not limited thereto. Depending on various conditions such as the direction of movement of the frame (200) during the process, the first groove (220) and the second groove (230) may be arranged on the third side wall (260) and the fourth side wall (270) of the frame (200), or may be arranged on all of the first side wall (240), the second side wall (250), the third side wall (260), and the fourth side wall (270).

Below, a structure in which the first groove and the second groove are arranged on all of the side walls of the frame is described as another embodiment.

### Embodiment 2

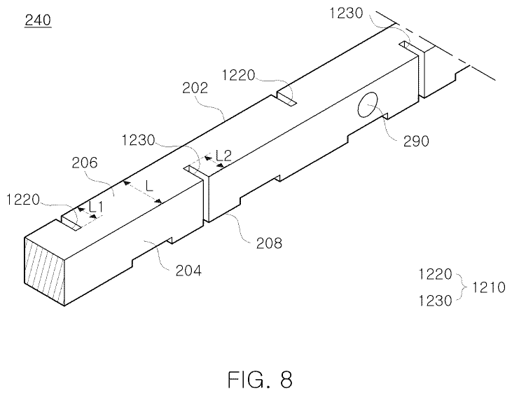

FIG. 7 is an exemplary diagram illustrating a frame of a pellicle according to embodiments, and FIG. 8 is an exemplary diagram illustrating a part of a side wall of the frame in FIG. 7.

Referring to FIGS. 7 and 8, a pellicle according to Embodiment 2 of the present inventive concept may include a pellicle membrane and a frame (1200). The pellicle may additionally include an adhesive layer disposed on a second surface (208) of the frame (1200) and a protective film disposed on the adhesive layer. Except for the configuration of the frame (1200), the configuration of the pellicle membrane, the adhesive layer, and the protective film may be implemented in the same manner as the configuration of the pellicle membrane (100), the adhesive layer (300), and the protective film (400) of Embodiment 1, and will not be described in detail.

The frame (1200) may include a plurality of grooves (1210) disposed on the frame (1200). The plurality of grooves (1210) may be respectively arranged on the inner peripheral wall surface (202) and the outer peripheral wall surface (204) of the frame (1200) along the circumferential direction of the frame (1200). In embodiments, the frame (1200) may include a plurality of first grooves (1220) arranged on the inner peripheral wall surface (202) of the frame (1200) and a plurality of second grooves (1230) arranged on the outer peripheral wall surface (204) of the frame (1200).

The plurality of first grooves (1220) may be arranged spaced apart from one another in the circumferential direction of the frame (1200) and may extend from the inner peripheral wall surface (202) of the frame (1200) toward the outer peripheral wall surface (204). The plurality of first grooves (1220) may penetrate the first surface (206) and the second surface (208) of the frame (1200) and may have a slit shape that extends from the inner peripheral wall surface (202) of the frame (1200) toward the outer peripheral wall surface (204). In embodiments, the plurality of first grooves (1220) may have a first extension length (L1) that extends from the inner peripheral wall surface (202) of the frame (1200) toward the outer peripheral wall surface (204) of the frame (1200) in a direction perpendicular to the inner peripheral wall surface (202). In embodiments, the first extension length (L1) of the plurality of first grooves (1220) may be 50% to 90% of the distance (L) between the inner peripheral wall surface (202) of the frame (1200) and the outer peripheral wall surface (204). In embodiments, as illustrated in FIGS. 7 and 8, the first extension length (L1) of the plurality of first grooves (1220) may be 50% of the distance (L) between the inner peripheral wall surface (202) of the frame (1200) and the outer peripheral wall surface (204), but is not limited thereto, and may be any number within a range of 50% to 90% of the distance (L) between the inner peripheral wall surface (202) of the frame (1200) and the outer peripheral wall surface (204).

The plurality of second grooves (1230) may be spaced apart from one another in the circumferential direction of the frame (1200) and may extend from the outer peripheral wall surface (204) of the frame (1200) toward the inner peripheral wall surface (202). The plurality of second grooves (1230) may penetrate the first surface (206) and the second surface (208) of the frame (1200) and may have a slit shape extending from the outer peripheral wall surface (204) of the frame (1200) toward the inner peripheral wall surface (202). In embodiments, the plurality of second grooves (1230) may have a second extension length (L2) extending from the outer peripheral wall surface (204) of the frame (1200) toward the inner peripheral wall surface (202) in a direction perpendicular to the outer peripheral wall surface (204). In embodiments, the second extension length (L2) of the plurality of second grooves (1230) may be 50% to 90% of the distance (L) between the inner peripheral wall surface (202) of the frame (1200) and the outer peripheral wall surface (204). In embodiments, as illustrated in FIGS. 7 and 8, the second extension length (L2) of the plurality of second grooves (1230) may be, but is not limited to, 50% of the distance (L) between the inner peripheral wall surface (202) of the frame (1200) and the outer peripheral wall surface (204), and may be any number within a range of 50% to 90% of the distance (L) between the inner peripheral wall surface (202) of the frame (1200) and the outer peripheral wall surface (204).

The plurality of first grooves (1220) and the plurality of second grooves (1230) may be arranged parallel to one another. In embodiments, the plurality of first grooves (1220) and the plurality of second grooves (1230) may be arranged to intersect one another along the circumferential direction of the frame (1200).

The plurality of first grooves (1220) and the plurality of second grooves (1230) may be arranged on all of the side walls of the frame (1200). In embodiments, as illustrated in FIGS. 7 and 8, the plurality of first grooves (1220) and the plurality of second grooves (1230) may be arranged on all of the first side wall (240), the second side wall (250), the third side wall (260), and the fourth side wall (270). In this case, the first groove (1220) and the second groove (1230) arranged on the first side wall (240) may be arranged in the same manner as the first groove (1220) and the second groove (1230) arranged on the second side wall (250), and the first groove (1220) and the second groove (1230) arranged on the third side wall (260) may be arranged in the same manner as the first groove (1220) and the second groove (1230) arranged on the fourth side wall (270), but are not limited thereto. Accordingly, the deformation of the frame (1200) may be minimized by the structure of the groove (1210) including the plurality of first grooves (1220) and the plurality of second grooves (1230), and in particular, the deformation of the frame (1200) in the third direction (Z) may be improved. Furthermore, even if the frame (1200) has a play in the first direction (X) or the second direction (Y) during the movement process of the frame (1200) or when pressure is applied, the play may be compensated for by the zigzag arrangement of the plurality of first grooves (1220) and the plurality of second grooves (1230), so that the deformation of the frame (1200) in the first direction (X) and the second direction (Y) may be significantly reduced.

Below, embodiments having a different structure from the first groove (1220) and the second groove (1230) of the frame (1200) is described.

### Example 3

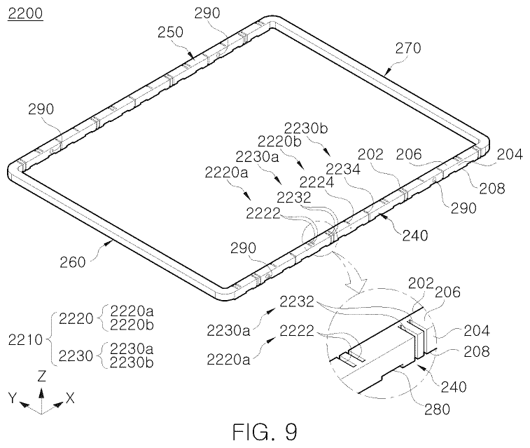

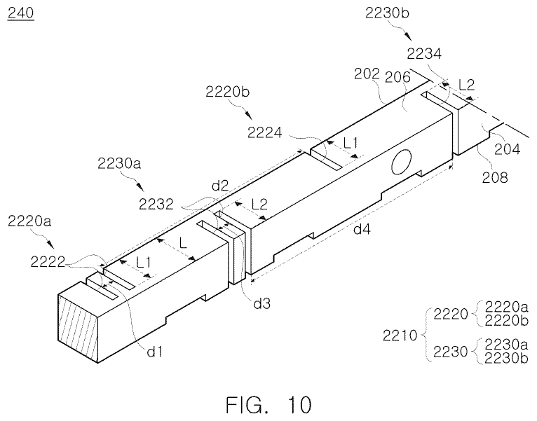

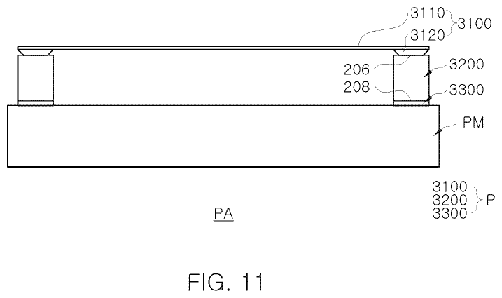

FIG. 9 is an exemplary drawing illustrating a frame of a pellicle according to embodiments, and FIG. 10 is an exemplary drawing illustrating a part of a side wall of the frame in FIG. 9.

Referring to FIGS. 9 and 10, a pellicle according to Example 3 of the present inventive concept may include a pellicle membrane and a frame (2200). The pellicle may optionally include an adhesive layer disposed on a second surface (208) of the frame (2200) and a protective film disposed on the adhesive layer. Except for the configuration of the frame (2200), the configuration of the pellicle membrane, the adhesive layer, and the protective film may be implemented in the same manner as the configuration of the pellicle membrane (100), the adhesive layer (300), and the protective film (400) of Example 1, and will not be described in detail.

The frame (2200) may include a plurality of grooves (2210) disposed on the frame (2200). The plurality of grooves (2210) may be respectively arranged on the inner peripheral wall surface (202) and the outer peripheral wall surface (204) of the frame (2200) along the circumferential direction of the frame (2200). In embodiments, the frame (2200) may include a plurality of first grooves (2220) arranged on the inner peripheral wall surface (202) of the frame (2200) and a plurality of second grooves (2230) arranged on the outer peripheral wall surface (204) of the frame (2200).

The plurality of first grooves (2220) may be arranged spaced apart from one another in the circumferential direction of the frame (2200) and may extend from the inner peripheral wall surface (202) of the frame (2200) toward the outer peripheral wall surface (204). The plurality of first grooves (2220) may penetrate the first surface (206) and the second surface (208) of the frame (2200) and may have a slit shape that extends from the inner peripheral wall surface (202) of the frame (2200) toward the outer peripheral wall surface (204). In embodiments, the plurality of first grooves (2220) may have a first extension length (L1) that extends from the inner peripheral wall surface (202) of the frame (2200) toward the outer peripheral wall surface (204) of the frame (2200) in a direction perpendicular to the inner peripheral wall surface (202). In embodiments, the first extension length (L1) of the plurality of first grooves (2220) may be 50% to 90% of the distance (L) between the inner peripheral wall surface (202) of the frame (2200) and the outer peripheral wall surface (204).

A plurality of second grooves (2230) may be spaced apart from one another in the circumferential direction of the frame (2200) and may extend from the outer peripheral wall surface (204) of the frame (2200) toward the inner peripheral wall surface (202). The plurality of second grooves (2230) may penetrate the first surface (206) and the second surface (208) of the frame (2200) and may have a slit shape extending from the outer peripheral wall surface (204) of the frame (2200) toward the inner peripheral wall surface (202). In embodiments, the plurality of second grooves (2230) may have a second extension length (L2) extending from the outer peripheral wall surface (204) of the frame (2200) toward the inner peripheral wall surface (202) in a direction perpendicular to the outer peripheral wall surface (204). In embodiments, the second extension length (L2) of the plurality of second grooves (2230) may be 50% to 90% of the distance (L) between the inner peripheral wall surface (202) and the outer peripheral wall surface (204) of the frame (2200).

The plurality of first grooves (2220) and the plurality of second grooves (2230) may be arranged parallel to one another. In embodiments, the plurality of first grooves (2220) and the plurality of second grooves (2230) may be arranged to intersect one another along the circumferential direction of the frame (2200).

The plurality of first grooves (2220) and the plurality of second grooves (2230) may be arranged on the first side wall (240) and the second side wall (250) of the frame (2200) as illustrated in FIG. 9, but are not limited thereto, and may be arranged on the third side wall (260) and the fourth side wall (270) instead of the first side wall (240) and the second side wall (250), or may be arranged on all of the side walls of the frame (2200).

In embodiments, the spacing between the plurality of first grooves (2220) may not be the same but may be different, and the spacing between the plurality of second grooves (2230) may not be the same but may be different.

In embodiments, the frame (2200) may include a first-first groove group (2220a) composed of a first-first groove (2222), which is a part of the plurality of first grooves (2220) arranged on the inner peripheral wall surface (202) of the frame (2200), and a first-second groove group (2220b) composed of a first-second groove (2224), which is another part of the plurality of first grooves (2220).

A plurality of first-first groove groups (2220a) and a plurality of first-second groove groups (2220b) may be arranged to intersect one another on the inner peripheral wall surface (202) of the frame (2200). A plurality of first-first grooves (2222) may be arranged in each first-first groove group (2220a), and the plurality of first-first grooves (222) may be arranged to be spaced apart from one another by a first interval (d1). The number of first-second grooves (2224) in each first-second groove group (2220b) may be different from the number of first-first grooves (2222) in each first-first groove group (2220a). In embodiments, as illustrated in FIG. 9, one 1-2 groove (2224) may be arranged in each 1-2 groove group (2220b). However, the present inventive concept is not limited thereto, and a plurality of 1-2 grooves (2224) may be arranged in each 1-2 groove group (2220b). The 1-1 groove group (2220a) and the 1-2 groove group (2220b) may be arranged to be spaced apart from one another by the same second interval (d2) on the inner peripheral wall surface (202) of the frame (2200). The first interval (d1) and the second interval (d2) may be different. The first interval (d1) may be smaller than the second interval (d2). The first extension length (L1) of the first-1 groove (2222) of the first-1 groove group (2220a) and the first-2 groove (2224) of the first-2 groove group (2220b) may be the same or different. In embodiments, as illustrated in FIG. 10, each 1-1 groove group (2220a) may include two 1-1 grooves (2222), each 1-2 groove group (2220b) may include one 1-2 groove (2224), and the first extension lengths (L1) of the 1-1 grooves (2222) of the 1-1 groove group (2220a) and the 1-2 grooves (2224) of the 1-2 groove group (2220b) may be arranged identically, but are not limited thereto, and in other examples, they may have different first extension lengths. The arrangement of the first groove (2220) of the present inventive concept is not limited thereto, and the first-first groove group (2220a) may include one, three or more first-first grooves (2222), and the first-second groove group (2220b) may include two, three or more first-second grooves (2224).

The frame (2200) may include a second-first groove group (2230a) composed of a second-first groove (2232), which is a part of a plurality of second grooves (2230) arranged on the outer peripheral wall surface (204) of the frame (2200), and a second-second groove group (2230b) composed of a second-second groove (2234), which is another part of a plurality of second grooves (2230). A plurality of 2-1 groove groups (2230a) and a plurality of 2-2 groove groups (2230b) may be arranged to intersect one another on the outer peripheral wall surface (204) of the frame (2200). A plurality of 2-1 grooves (2232) may be arranged in each 2-1 groove group (2230a), and the plurality of 2-1 grooves (2232) may be arranged to be spaced apart from one another by a third interval (d3). The number of 2-2 grooves (2234) in each 2-2 groove group (2230b) may be different from the number of 2-1 grooves (2232) in each 2-1 groove group (2230a). In embodiments, as illustrated in FIG. 9, one 2-2 groove (2234) may be arranged in each 2-2 groove group (2230b). However, the present inventive concept is not limited thereto, and one 2-2 groove (2234) may be arranged in multiple numbers in each 2-2 groove group (2230b). The 2-1 groove group (2230a) and the 2-2 groove group (2230b) may be arranged to be spaced apart from one another by the same fourth interval (d4) on the outer peripheral wall surface (204) of the frame (2200). The third interval (d3) may be smaller than the fourth interval (d4). The fourth gap (d4) between the 2-1st groove group (2230a) and the 2-2nd groove group (2230b) may be the same as the second gap (d2) between the 1-1st groove group (2220a) and the 1-2nd groove group (2220b), but is not particularly limited thereto. The second extension lengths (L2) of the 2-1st groove (2232) of the 2-1st groove group (2230a) and the 2-2nd groove (2234) of the 2-2nd groove group (2230b) may be the same or different. In embodiments, as illustrated in FIG. 10, each 2-1 groove group (2230a) may include two 2-1 grooves (2232), and each 2-2 groove group (2230b) may include one 2-2 groove (2234), and the second extension lengths of the 2-1 grooves (2232) of the 2-1 groove group (2230a) and the 2-2 grooves (2234) of the 2-2 groove group (2230b) may be arranged identically, but are not limited thereto, and in other examples, may have different second extension lengths. In embodiments, the first extension length and the second extension length may be identical, but in embodiments, they may be different. The arrangement of the second groove (2230) of the present inventive concept is not limited thereto, and is not limited thereto, and the 2-1 groove group (2230a) may include one, three or more 2-1 grooves (2232), and the 2-2 groove group (2230b) may include two, three or more 2-2 grooves (2234).

The plurality of first-first groove groups (2220a) and the plurality of second-first groove groups (2230a) may be arranged at positions adjacent to one another on the inner peripheral wall surface (202) and the outer peripheral wall surface (204) of the frame (2200). The first interval (d1) and the third interval (d3) may be the same, but are not limited thereto. The plurality of first-second groove groups (2220b) and the plurality of second-second groove groups (2230b) may be arranged at positions adjacent to one another on the inner peripheral wall surface (202) and the outer peripheral wall surface (204) of the frame (2200). The second interval (d2) and the fourth interval (d4) may be the same, but are not limited thereto.

The frame (2200) is described above as including a first-first groove group (2220a) composed of a part of a plurality of first grooves (2220), a first-second groove group (2220b) composed of another part of a plurality of first grooves (2220), a second-first groove group (2230a) composed of a part of a plurality of second grooves (2230), and a second-second groove group (2230b) composed of another part of a plurality of second grooves (2230), but is not limited thereto, and the frame (2200) may additionally include a groove group other than the first-first groove group (2220a), the first-second groove group (2220b), the second-first groove group (2230a), and the second-second groove group (2230b). In addition, the first-first groove group (2220a) and the first-second groove group (2220b) have been described as including a plurality of first-first grooves (2222) and a plurality of first-second grooves (2224), but as another embodiment, they may include one first-first groove (2222) and one first-second groove (2224). In addition, the second-first groove group (2230a) and the second-second groove group (2230b) have been described as including a plurality of second-first grooves (2232) and a plurality of second-second grooves (2234), but as another embodiment, they may include one second-first groove (2232) and one second-second groove (2234), which will also fall within the scope of the present inventive concept.

The photomask assembly including a pellicle and a photomask including a pellicle membrane of a different form than the pellicle membrane described in the above embodiments is described below.

### Example 4

FIG. 11 is an exemplary diagram illustrating a photomask assembly according to embodiments.

The photomask assembly (PA) may include a photomask (PM) and a pellicle (P) protecting the photomask (PM) from the outside.

The pellicle (P) may include a pellicle membrane (3100) and a frame (3200) that supports the pellicle membrane (3100). The pellicle (P) may optionally include an adhesive layer (3300) that is arranged on a second surface (208) of the frame (3200). The pellicle (P) may optionally include a protective film that is arranged to be detachable on the adhesive layer (3300). Except for the configuration of the above pellicle membrane (3100), the configuration of the frame (3200), the adhesive layer (3300), and the protective film may be implemented in the same manner as the configuration of the frame (200, 1200, 2200), the adhesive layer (300), and the protective film (400) of the above embodiments 1 to 3, and thus, a detailed description thereof will be omitted.

The above pellicle membrane (3100) may include a membrane body (3110) and a border (3120) formed integrally with the membrane body (3110). The membrane body (3110) may have a flat shape. The border (3120) may extend along the peripheral edge of one side of the membrane body (3110) and be formed integrally with the membrane body (3110). The border (3120) may provide mechanical stability to the membrane body (3100) and may be configured to reduce the possibility that the membrane body (3110) is deformed from the planar shape of the membrane body (3110). The border (3120) may have various shapes. In embodiments, as illustrated in FIG. 11, the border (3120) may have a cross-section of an inverted trapezoidal shape, but is not limited thereto, and may be configured to have various cross-sectional shapes such as a quadrangular shape. The thickness of the border (3120) is not particularly limited, and may be configured to have an appropriate thickness as long as it may provide mechanical stability to the membrane body (3110). The border (3120) may be connected by directly contacting the first surface (206) of the frame (3200). The above border (3120) and frame (3200) may be connected by using the van der Waals force between one surface of the border (3120) and the first surface (206) of the frame (3200) without the intervention of a separate adhesive layer or other connecting means. Accordingly, the process of arranging a separate adhesive layer or other connecting means and the resulting risks and time may be reduced, and mass production of pellicles (P) may be easily implemented.

The membrane body (3110) and the border (3120) may be formed integrally of carbon nanotubes. The membrane body (3110) may have a thickness sufficiently thin to allow EUV light or electron beams to pass through it. The membrane body (3110) may have a transmittance of 90% or more. In embodiments, the membrane body (3110) may have a transmittance of 95% or more. However, in the present embodiment, the membrane body (3110) is not limited to the transmittance range and may be appropriately changed according to various lithography process conditions. The membrane body (3110) may be formed of a carbon nanotube layer having a thickness of several nm to several tens nm to secure a transmittance above a certain standard. In embodiments, the membrane body (3110) may be a carbon nanotube layer having a thickness of less than or equal to 20 nm, but is not limited thereto. In embodiments, the membrane body (3110) may have a very thin thickness of about 5 nm to 20 nm. The membrane body (3110) may be free-standing over a large area due to its own structure and may be safely supported on a frame (3200) by a border (3120).

The pellicle and the photomask assembly including the pellicle according to the example embodiments may minimize deformation of the pellicle, and in particular, the pellicle membrane may be arranged on the frame in a free-standing structure to minimize deformation and stress of the pellicle.

As set forth above, according to embodiments, there may be provided a pellicle and photomask assembly in which deformation of a pellicle may be minimized, and in detail, a pellicle membrane is arranged in a frame in a free-standing structure to minimize deformation and stress of the pellicle.

While example embodiments have been illustrated and described above, it will be apparent to those skilled in the art that modifications and variations could be made without departing from the scope of the present inventive concept as defined by the appended claims.

What is claimed is:

1. A pellicle comprising:
a pellicle membrane formed of carbon nanotubes; and
a frame directly contacting and connected to a peripheral edge of one side of the pellicle membrane.

2. The pellicle of claim 1, wherein the frame includes:
a first surface that connects both ends of an inner peripheral wall surface of the frame and an outer peripheral wall surface of the frame and is connected to the peripheral edge of one side of the pellicle membrane, and a second surface, facing the first surface,
a plurality of first grooves in the form of slits that are spaced apart from one another in a circumferential direction of the frame and extend from the inner peripheral wall surface of the frame toward the outer peripheral wall surface of the frame and penetrate the first surface and the second surface of the frame; and
a plurality of second grooves in the form of slits that are spaced apart from one another in the circumferential direction of the frame and extend from the outer peripheral wall surface of the frame toward the inner peripheral wall surface of the frame and penetrate the first surface and the second surface of the frame.

3. The pellicle of claim 2, wherein the plurality of first grooves and the plurality of second grooves are arranged to intersect one another along the circumferential direction of the frame.

4. The pellicle of claim 3, wherein an extension length of each of the plurality of first grooves and the plurality of second grooves is 50% to 90% of a distance between the inner peripheral wall surface and the outer peripheral wall surface of the frame.

5. The pellicle of claim 3, wherein the plurality of first grooves and the plurality of second grooves are arranged on at least a portion of side walls of the frame that face one another.

6. The pellicle of claim 3, wherein the plurality of first grooves and the plurality of second grooves are arranged on entire side walls of the frame.

7. The pellicle of claim 3, wherein:
the frame is configured in a quadrangular shape, and includes a first side wall and a second side wall that are opposed to one another, and a third side wall and a fourth side wall that connect both ends of the first side wall and both ends of the second side wall, and
the plurality of first grooves and the plurality of second grooves are arranged on the first side wall and the second side wall or the third side wall and the fourth side wall.

8. The pellicle of claim 2, wherein the frame includes a plurality of adhesive grooves that are arranged spaced apart from one another in the circumferential direction of the frame on the second surface.

9. The pellicle of claim 8, wherein each of the adhesive grooves is positioned between the first groove and the second groove that are adjacent to one another on the second surface.

10. The pellicle of claim 1, wherein the pellicle membrane has a thickness of 5 nm to 20 nm.

11. The pellicle of claim 1, wherein the pellicle membrane includes a membrane body having a flat shape and a border that extends along a peripheral edge of one side of the membrane body and is integrally formed with the membrane body and is connected to a first surface of the frame by contacting the first surface of the frame, and
the membrane body and the border are formed of carbon nanotubes.

12. The pellicle of claim 1, wherein an adhesive layer is disposed on a second surface of the frame opposite to a first surface of the frame and that adheres the frame to a photomask.

13. The pellicle of claim 12, wherein a protective film is disposed detachably on a photomask adhesive surface of the adhesive layer opposite to the second surface of the frame.

14. The pellicle of claim 1, wherein a vent hole is formed in the frame that penetrates an inner peripheral wall surface of the frame and an outer peripheral wall surface of the frame.

15. A pellicle comprising:
a pellicle membrane formed of carbon nanotubes; and
a frame including a first surface directly contacting and connected to a peripheral edge of one side of the pellicle membrane and a second surface, facing the first surface,
wherein the frame includes a plurality of grooves in the form of slits that are respectively arranged on an inner peripheral wall surface and an outer peripheral wall surface of the frame and intersect one another along a peripheral direction of the frame and penetrate the first surface of the frame and the second surface of the frame.

16. The pellicle of claim 15, wherein an extension length of each of the plurality of grooves is 50% to 90% of a distance between the inner peripheral wall surface of the frame and the outer peripheral wall surface of the frame.

17. The pellicle of claim 15, wherein the plurality of grooves are arranged on at least a portion of side walls of the frame that face one another.

18. The pellicle of claim 15, comprising:
an adhesive layer arranged on the second surface of the frame and adhering the frame to a photomask; and
a protective film detachably arranged on a photomask adhesive surface of the adhesive layer opposite to the second surface of the frame.

19. A photomask assembly comprising:
a photomask having a coupling surface; and
a pellicle including a pellicle membrane formed of carbon nanotubes and a frame having a first surface directly contacting and connected to a peripheral edge of one side of the pellicle membrane and a second surface coupled to the coupling surface.

20. The photomask assembly of claim 19, wherein the frame includes:
a plurality of first grooves in the form of slits spaced apart from one another in a circumferential direction of the frame and extending from an inner peripheral wall surface of the frame toward an outer peripheral wall surface of the frame and penetrating the first surface of the frame and the second surface of the frame; and
a plurality of second grooves in the form of slits spaced apart from one another in the circumferential direction of the frame and extending from the outer peripheral wall surface of the frame toward the inner peripheral wall surface of the frame and penetrating the first surface of the frame and the second surface of the frame,
wherein the plurality of first grooves and the plurality of second grooves are arranged to intersect one another along the circumferential direction of the frame.
